(19) United States
(12) Patent Application Publication
(10) Pub. No.: US 2023/0395440 A1
(43) Pub. Date: Dec. 7, 2023

(54) METHOD OF HANDLING TEST PAD AND METHOD OF FABRICATING SEMICONDUCTOR DEVICE

(71) Applicant: WUHAN XINXIN SEMICONDUCTOR MANUFACTURING CO., LTD., Wuhan (CN)

(72) Inventors: Qiong ZHAN, Wuhan (CN); Jun ZHOU, Wuhan (CN); Sheng HU, Wuhan (CN)

(21) Appl. No.: 18/081,230

(22) Filed: Dec. 14, 2022

(30) Foreign Application Priority Data
Jun. 7, 2022 (CN) 202210639289.6

(51) Int. Cl. H01L 21/66; H01L 23/544; B23K 26/03

(52) U.S. Cl. CPC H01L 22/32; B23K 2101/40; B23K 26/034; H01L 23/544

(57) ABSTRACT

A method of handling a test pad and a method of fabricating a semiconductor device are disclosed. The method of handling a test pad includes: providing a substrate formed thereon with a first insulating dielectric layer and a first test pad in the first insulating dielectric layer, wherein a surface of the first test pad is at least partially exposed from the first insulating dielectric layer, and there is a probe mark with a protrusion resulting from testing with probe tips on the surface portion of the first test pad exposed from the first insulating dielectric layer; and heating and melting the protrusion by laser annealing, thereby reducing a height of the protrusion. This invention can ensure good flatness of a surface to be bonded while enabling reduced process complexity and preventing metal contamination of the surface to be bonded.

### CROSS-REFERENCES TO RELATED APPLICATION

This application claims the priority of Chinese patent application number 202210639289.6, filed on Jun. 7, 2022, the entire contents of which are incorporated herein by reference.

### TECHNICAL FIELD

The present invention relates to the field of semiconductor integrated circuit (IC) fabrication technology and, in particular, to a method of handling a test pad and a method of fabricating a semiconductor device.

### BACKGROUND

In 3D IC processes, wafers or dies can be tested with probe tips to determine whether they function properly, before they are stacked and bonded. This can reduce yield loss of wafers or dies, in particular when multiple wafers or dies are to be stacked and bonded together.

Fusion and hybrid bonding processes are demanding in terms of surface conditions of the wafers or dies to be bonded. The surfaces to be bonded are required to be very flat. However, yield testing will leave probe marks on test pads on a wafer, which have a diameter of approximately 2-20 μm and include depressions and protrusions. Such protrusions may protrude as high as 2 μm above a top surface of an insulating material layer around the test pad, significantly degrading the wafer surface to be bonded.

Currently available methods for ensuring good flatness of a surface to be bonded include those described below.

(1) Referring to FIGS. 1a and 1b, a first insulating material layer 11, a second insulating material layer 12 and a third insulating material layer 13 are stacked from the bottom upwards. A metal interconnect 14 is formed in the first insulating material layer 11, and a first test pad 15 and a second test pad 16 are each formed in both the second insulating material layer 12 and the third insulating material layer 13. The first test pad 15 and the second test pad 16 are arranged in parallel for external connection of the metal interconnect 14. A top surface of the first test pad 15 is exposed from the third insulating material layer 13, while the second test pad 16 is buried in the third insulating material layer 13. After testing with probe tips, a probe mark is left in the surface of the first test pad 15. A protrusion D1 in the probe mark projects far beyond a top surface of the third insulating material layer 13. An etching process is employed to remove the first test pad 15 exposed from the third insulating material layer 13 and thus eliminate the probe mark, and a fourth insulating material layer 17 is formed over the third insulating material layer 13 and the surface exposed as a result of the removal of the first test pad 15. A conductive structure 18 is then formed on the parallel second test pad 16 to enable external connection of the metal interconnect 14. This method requires the design of two parallel test pads, leading to increased wiring complexity.

(2) Referring to FIGS. 2a and 2b, a first insulating material layer 21, a second insulating material layer 22 and a third insulating material layer 23 are stacked from the bottom upwards. A metal interconnect 24 is formed in the first insulating material layer 21, and a test pad is formed in both the second insulating material layer 22 and the third insulating material layer 23 for external connection of the metal interconnect 14. The test pad includes a first metal layer 251 in the second and third insulating material layers 22, 23 and a second metal layer 252 residing on a top surface of the first metal layer 251. A top surface of the second metal layer 252 is exposed from the third insulating material layer 23. After testing with probe tips, a probe mark is left, which affects only the second metal layer 252. A protrusion D2 in the probe mark projects far beyond a top surface of the third insulating material layer 23. The exposed second metal layer 252 is removed, thus eliminating the probe mark. A third metal layer 253 is then grown to take up the space resulting from the removal of the second metal layer 252. A fourth insulating material layer 26 is formed over the third insulating material layer 23 and the third metal layer 253, and a conductive structure 27 is formed on the third metal layer 253 for external connection of the metal interconnect 24. This method requires the test pad to consist of at least two layers, and control is necessary in the removal process so that only the second metal layer 252 is removed. Moreover, after the removal of the second metal layer 252, it is necessary to grow the third metal layer 253. Thus, the method suffers from high process complexity and hence very high cost.

Therefore, there is urgent need to modify and improve the existing method for ensuring good flatness of a surface to be bonded.

### SUMMARY OF THE INVENTION

It is an object of the present invention to provide a method of handling a test pad and a method of fabricating a semiconductor device, which can ensure very good flatness of a surface to be bonded with reduced process complexity and the prevention of metal contamination on the surface to be bonded.

To this end, the present invention provides a method of handling a test pad, including:
providing a substrate formed thereon with a first insulating dielectric layer and a first test pad in the first insulating dielectric layer, wherein a surface of the first test pad is at least partially exposed from the first insulating dielectric layer, and there is a probe mark with a protrusion resulting from testing with probe tips on the surface portion of the first test pad exposed from the first insulating dielectric layer; and
heating and melting the protrusion by laser annealing, thereby reducing a height of the protrusion.

Optionally, the protrusion may project from the surface of the first test pad beyond a surface of the first insulating dielectric layer.

Optionally, the laser annealing may be accomplished with a laser beam, which is a monochromatic laser beam or a superimposition of at least two monochromatic laser beams.

Optionally, the protrusion may be eliminated through heating and melting it by laser annealing and thereby fusing it with the first test pad.

Optionally, the laser annealing may be accomplished with a laser beam with an energy density, which enables the first test pad to be heated at a temperature at least equal to a melting point of a material of the first test pad.

Optionally, the material of the first test pad may be a metal alloy containing aluminum and copper, wherein the heating temperature ranges from 600° C. to 700° C.

Optionally, the laser annealing may be accomplished by continuous spot irradiation or point-by-point scanning irradiation, which does not affect any other region than the first test pad exposed from the first insulating dielectric layer.

Optionally, a temperature at a bottom side of the first test pad may be not higher than 500° C.

Optionally, the method may further include, after the protrusion is heated and molten by laser annealing, cleaning the surface of the first test pad.

The present invention also provides a method of fabricating a semiconductor device, including:
providing a substrate formed thereon with a first insulating dielectric layer and a first test pad in the first insulating dielectric layer, wherein a surface of the first test pad is at least partially exposed from the first insulating dielectric layer, and there is a probe mark with a protrusion resulting from testing with probe tips on the surface portion of the first test pad exposed from the first insulating dielectric layer;
heating and melting the protrusion by laser annealing, thereby reducing a height of the protrusion;
forming a second insulating dielectric layer, which covers the first test pad and the first insulating dielectric layer; and
planarizing the second insulating dielectric layer so that the remaining height of the protrusion is smaller than a height of a surface of the planarized second insulating dielectric layer.

Optionally, the protrusion may be eliminated through heating and melting it by laser annealing and thereby fusing it with the first test pad.

Optionally, a metal interconnect may be formed in the first insulating dielectric layer, wherein the first test pad is electrically connected at the bottom to the metal interconnect, and wherein the method further includes:
providing a wafer or die; and bonding a side of the second insulating dielectric layer away from the substrate to the wafer or die.

Optionally, the method may further include, subsequent to the planarization of the second insulating dielectric layer and prior to the bonding of the side of the second insulating dielectric layer away from the substrate to the wafer or die,
forming a conductive structure electrically connected to the first test pad in the second insulating dielectric layer,
or subsequent to the bonding of the side of the second insulating dielectric layer away from the substrate to the wafer or die,
forming a conductive structure, which extends through the wafer or die into the second insulating dielectric layer and is electrically connected to the first test pad.

Optionally, a second test pad electrically connected at the bottom to the metal interconnect may be further formed in the first insulating dielectric layer, wherein the method further includes, subsequent to the planarization of the second insulating dielectric layer and prior to the bonding of the side of the second insulating dielectric layer away from the substrate to the wafer or die,
forming a conductive structure, which extends through the second insulating dielectric layer into the first insulating dielectric layer and is electrically connected to the second test pad,
or subsequent to the bonding of the side of the second insulating dielectric layer away from the substrate to the wafer or die,
forming conductive structure, which extends through the wafer or die and the second insulating dielectric layer into the first insulating dielectric layer and is electrically connected to the second test pad.

Compared with the prior art, the present invention offers the following benefits:

1. In the method of handling a test pad, reducing the height of the protrusion in the probe mark resulting from testing with probe tips on the surface of the first test pad exposed from the first insulating dielectric layer through melting it by laser annealing ensures good flatness of the surface to be bonded while enabling reduced process complexity, increased handling efficiency and lower cost.

2. In the method of fabricating a semiconductor device, reducing the height of the protrusion in the probe mark resulting from testing with probe tips on the surface of the first test pad exposed from the first insulating dielectric layer through heating and melting it by laser annealing so that the remaining height of the protrusion is smaller than the height of the surface of the planarized second insulating dielectric layer ensures good flatness of the surface to be bonded while enabling reduced process complexity and preventing metal contamination of the surface to be bonded.

### BRIEF DESCRIPTION OF THE DRAWINGS

FIGS. 1a to 1b are schematic diagrams of devices in a method for ensuring good flatness of a surface to be bonded;

FIGS. 2a to 2b are schematic diagrams of devices in another method for ensuring good flatness of a surface to be bonded;

FIG. 3 is a flowchart of a method of handling a test pad according to an embodiment of the present invention;

FIGS. 4a to 4d are schematic diagrams of devices in the method of FIG. 3; and

FIGS. 5a to 5b are schematic diagrams showing external connection of a metal interconnect with parallel test pads according to an embodiment of the present invention.

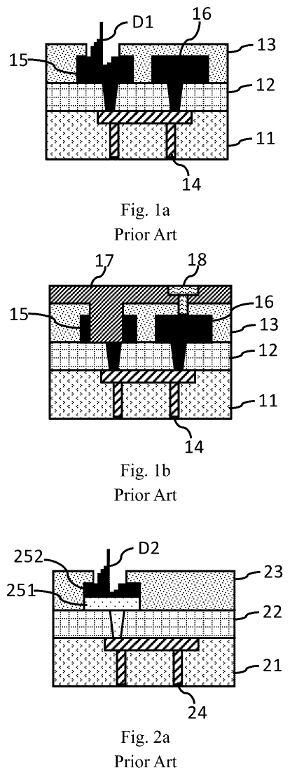

The following is a list of reference numerals used in FIGS. 1a to 5b:

11—First Insulating Material Layer; 12—Second Insulating Material Layer; 13—Third Insulating Material Layer; 14—Metal Interconnect; 15—First Test Pad; 16—Second Test Pad; 17—Fourth Insulating Material Layer; 18—Conductive Structure; 21—First Insulating Material Layer; 22—Second Insulating Material Layer; 23—Third Insulating Material Layer; 24—Metal Interconnect; 251—First Metal Layer; 252—Second Metal Layer; 253—Third Metal Layer; 26—Fourth Insulating Material Layer; 27—Conductive Structure; 31—First Insulating Dielectric Layer; 311—First Insulating Material Layer; 312—Second Insulating Material Layer; 313—Third Insulating Material Layer; 32—First Test Pad; 321—First Conductive Plug; 322—First Bond Pad; 33—Metal Interconnect; 331—Second Conductive Plug; 332—Metal Wire; 34—Second Insulating Dielectric Layer; 35—Conductive Structure; 36—Second Test Pad.

### DETAILED DESCRIPTION

Objects, features and advantages of the present invention will become more apparent upon reading the following more detailed description of the present invention, which is set forth by way of particular embodiments with reference to the accompanying drawings. Note that the figures are provided in a very simplified form not necessarily drawn to exact scale and for the only purpose of facilitating easy and clear description of the embodiments.

In an embodiment of the present invention, there is provided a method of handling a test pad. FIG. 3 is a flowchart of this method. As shown in FIG. 3, the method includes:
in step S11, providing a substrate formed thereon with a first insulating dielectric layer and a first test pad in the first insulating dielectric layer, wherein a surface of the first test pad is at least partially exposed from the first insulating dielectric layer, and there is a probe mark with a protrusion resulting from testing with probe tips on the surface portion of the first test pad exposed from the first insulating dielectric layer; and
in step S12, heating and melting the protrusion in the probe mark by a laser annealing process, thereby reducing a height of the protrusion in the probe mark.

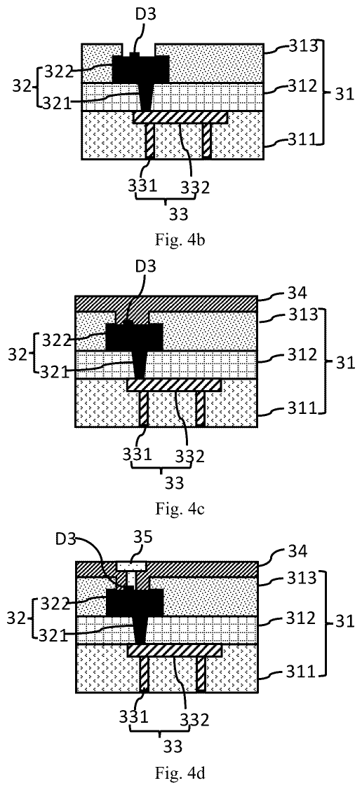

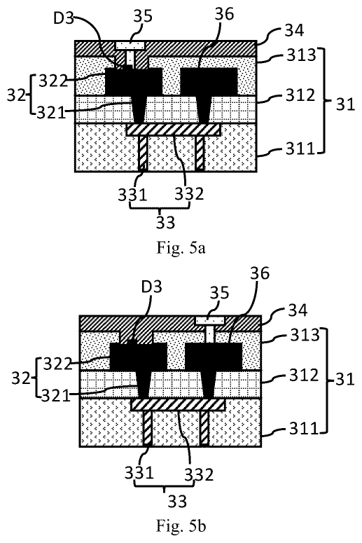

The method according to the present embodiment will be described in greater detail below with reference to FIGS. 4a to 4d and FIGS. 5a to 5b. FIGS. 4a to 4d and FIGS. 5a to 5b are schematic longitudinal cross-sectional views of semiconductor devices.

In step S11, a substrate (not shown) is provided, the substrate is formed thereon with a first insulating dielectric layer 31 and a first test pad 32 in the first insulating dielectric layer 31. A surface of the first test pad 32 is at least partially exposed from the first insulating dielectric layer 31, and there is a probe mark with a protrusion resulting from testing with probe tips on the surface portion of the first test pad 32 exposed from the first insulating dielectric layer 31.

In particular, when the protrusion in the probe mark projects from the surface of the first test pad 32 beyond a surface of the first insulating dielectric layer 31, flatness of a surface to be bonded subsequently will be seriously affected.

It is to be noted that there may be source regions, drain regions, well regions, solation structures and other components in the substrate and gates, spacer and other components in the first insulating dielectric layer 31.

The first insulating dielectric layer 31 may be a stack of several layers. In the embodiment shown in FIG. 4a, the first insulating dielectric layer 31 includes a first insulating material layer 311, a second insulating material layer 312 and a third insulating material layer 313, which are stacked from the bottom upwards. The first test pad 32 includes a first conductive plug 321 in the second insulating material layer 312 and a first bond pad 322 in the third insulating material layer 313. The first bond pad 322 is electrically connected to the first conductive plug 321, and a surface of the first bond pad 322 is partially exposed from the third insulating material layer 313. The surface portion of the first bond pad 322 exposed from the third insulating material layer 313 is just the aforementioned surface portion of the first test pad 32 exposed from the first insulating dielectric layer 31. It is to be noted that the first insulating dielectric layer 31 is not limited to being structured in the way as shown in FIG. 4a.

After testing with probe tips which are brought into contact with the first test pad 32, a probe mark will be left on the surface of the first test pad 32 (i.e., the surface of the first bond pad 322 in FIG. 4a). The probe mark includes a protrusion D3 and a depression D4. A height of the protrusion D3 is much greater than a height of the third insulating material layer 313. That is, the protrusion D3 projects from the surface of the first test pad 32 beyond the surface of the third insulating material layer 313. For example, the height of the protrusion D3 may be as greater as about 2 μm. This significantly degrades surface flatness of the semiconductor device. Moreover, if the semiconductor device is to be subsequently bonded to a wafer at the surface with the protrusion D3, the non-flat surface will also make it impossible to achieve normal bonding.

A metal interconnect 33 is formed in the first insulating dielectric layer 31, and the first test pad 32 is electrically connected to the metal interconnect 33. As shown in FIG. 4a, the metal interconnect 33 formed in the first insulating material layer 311 includes second conductive plugs 331 and a metal wire 332. The metal wire 332 is electrically connected to the second conductive plugs 331 on one side and to the first conductive plug 321 on the other side. The side of the metal wire 332 where it is in contact with the first conductive plug 321 coincides with a bottom side of the first test pad 32. It is to be noted that the metal interconnect 33 is not limited to being structured in the way as shown in FIG. 4a.

Additionally, in the first insulating dielectric layer 31, it is impossible to arrange either only the first test pad 32, as shown in FIGS. 4a to 4d, or both the first test pad 32 and a second test pad 36, as shown in FIGS. 5a to 5b, for external connection of the metal interconnect 33. In the latter case, the first test pad 32 and the second test pad 36 are both electrically connected at the bottom to the metal interconnect 33 and arranged in parallel for external connection of the metal interconnect 33. The second test pad 36 may include a third conductive plug (not labeled) in the second insulating material layer 312 and a second bond pad (not labeled) in the third insulating material layer 313. The second bond pad is electrically connected to the third conductive plug, which is in turn electrically connected to the metal wire 332.

The first insulating dielectric layer 31 may be formed of a conventional insulating material in the art, which may include at least one of silicon oxide, silicon nitride, silicon oxynitride, silicon carbonitride and other insulating materials. Each of the first test pad 32 and the second test pad 36 may be formed of a metal or a metal alloy. The metal alloy may include at least two of aluminum, tin, copper, nickel, gold, etc. The metal interconnect 33 may be formed of a conventional metallic material in the art, which may include at least one of aluminum, tungsten, copper, titanium and other metallic materials. The material of the metal wire 332 may be either the same as or different from that of the second conductive plugs 331.

In step S12, a laser annealing process is performed to heat and melt the protrusion D3, thereby reducing its height.

When the protrusion D3 is particularly high (e.g., it projects from the surface of the first test pad 32 beyond the surface of the first insulating dielectric layer 31), its height may be reduced so that the protrusion is below a surface of a subsequently formed and planarized second insulating dielectric layer (i.e., the second insulating dielectric layer 34 shown in FIGS. 4c to 4d and FIGS. 5a to 5b). In this way, the protrusion D3 will not be exposed and thus will not cause metal contamination during the planarization process on the second insulating dielectric layer 34. Moreover, when the semiconductor device is subsequently bonded to a wafer at the surface with the protrusion D3, abnormal bonding due to non-flatness of the surface can be avoided. Further, even when the protrusion D3 is not very high (e.g., the protrusion D3 projects from the surface of the first test pad 32 not beyond the surface of the first insulating dielectric layer 31), the presence of the protrusion D3 will lead to a degradation in the performance of the device.

During the laser annealing process, a laser beam L from a laser device (indicated by the arrows in FIG. 4a) is irradiated on the protrusion D3 on the first test pad 32 exposed from the first insulating dielectric layer 31. Preferably, the irradiation does not affect any other region than the first test pad 32 exposed from the first insulating dielectric layer 31. It is possible to irradiate only the protrusion D3, or both the protrusion D3 and a surrounding portion of the first test pad 32 (including part of the depression D4), or the entire portion of the first test pad 32 exposed from the first insulating dielectric layer 31. After being molten, the material of the protrusion D3 flows down onto the other part of the first test pad 32, leading to a reduction in the height of the protrusion D3. Further, the molten material of the protrusion D3 may flow into and fill up the depression D4. As a result, after being cooled, both the protrusion D3 and the depression D4 will disappear from the surface of the first test pad 32. The protrusion D3 may be eliminated by fusing it with part of the first test pad 32. As shown in FIG. 4b, after the protrusion D3 is heated and molten in the laser annealing process, the height the protrusion D3 is reduced to be smaller than the height of the third insulating material layer 313.

It is to be noted that, as a result of being heated and molten in the laser annealing process, the protrusion D3 may be either only shortened or totally eliminated (i.e., both the protrusion and the depression disappear, and the portion of the first test pad 32 exposed from the first insulating dielectric layer 31 gains a new flat surface).

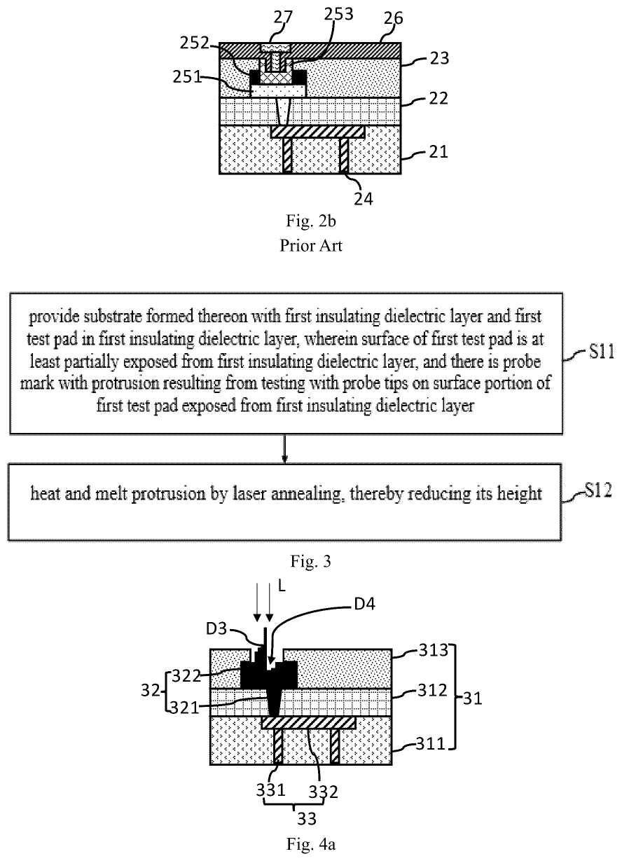

Compared with the approach shown in FIGS. 1a and 1b in which the first test pad 15 is discarded and the external connection of the metal interconnect 14 is instead accomplished by the second test pad 16 and with the approach shown in FIGS. 2a and 2b in which a partial thickness of the test pad is removed and the test pad is then re-thickened, shortening or eliminating the protrusion D3 by fusing it with the first test pad 32 through heating and melting it with laser annealing according to the present embodiment entails a simplest process that solves the problem of protrusions in probe mark defects. Moreover, after the protrusion is shortened or eliminated, the first test pad 32 remains useful, resulting an additional significant reduction in process complexity.

In addition, the laser beam used in the laser annealing process may be a monochromatic laser beam or a superimposition of at least two monochromatic laser beams. The monochromatic laser beam may be any of various laser beams known in the art, such as those in the wavelength regions from near ultraviolet through far infrared. Preferably, the monochromatic laser beam may be a red, green, yellow or violet laser beam, and the superimposition of at least two monochromatic laser beams may be a superimposition of red and green laser beams, or a superimposition of red and violet laser beams.

The laser beam used in the laser annealing process may have an energy density, which enables the first test pad 32 to be heated at a temperature that is at least equal to a melting point of the material of the first test pad 32.

Depending on the material of the first test pad 32, a suitable laser beam wavelength and irradiation duration may be chosen to allow the laser beam used in the laser annealing process to achieve an energy density, which achieves melting of the material of the first test pad 32 while not affecting any other component of the device. A shorter laser beam wavelength and/or a longer irradiation duration enables the first test pad 32 to be heated and molten at a higher temperature. A shorter laser beam wavelength enables the heating beam to reach a greater depth in the first test pad 32.

Preferably, a temperature at and below the bottom side of the first test pad 32 is not higher than 500° C. For example, if the material of the first test pad 32 is a metal alloy containing aluminum and copper, then the energy density of the laser beam used in the laser annealing process must enable the first test pad 32 to be heated at a temperature of 600-700° C., which is required by melting of the first test pad 32. However, although the laser beam acts only on the surface of the heated object, there will be a temperature gradient decreasing from the surface of the object. Therefore, in order to prevent any component below the first test pad 32 from being damaged, as shown in FIG. 4a, a temperature at the interface between the first test pad 32 and the metal interconnect 33 and a temperature of the underlying metal interconnect 33 shall not be higher than 500° C. The laser beam used in the laser annealing process may be a green laser beam.

Further, the laser annealing may be accomplished by continuous spot irradiation or point-by-point scanning irradiation. In case of a large area of the portion of the first test pad 32 exposed from the first insulating dielectric layer 31, continuous spot irradiation is preferred, which includes irradiating a portion of the first test pad 32 with a large stationary laser beam spot for a long period of time until the irradiated portion is melted. This approach is efficient. In case of a small area of the portion of the first test pad 32 exposed from the first insulating dielectric layer 31, in order to avoid the irradiation from affecting the first insulating dielectric layer 31 around the first test pad 32, point-by-point scanning irradiation is preferred, which includes irradiating a portion of the first test pad 32 with a very small laser beam spot (point) for a short period of time, moving the spot to the next portion after the previous portion has been molten, and repeating these steps until the whole intended portion has been so treated.

After the protrusion D3 has been heated and molten in the laser annealing process, the method may further include cleaning the surfaces of the first test pad 32 and the first insulating dielectric layer 31.

As can be seen from the above description, in the method of the present invention, the protrusion in the probe mark resulting from testing with probe tips on the surface of the portion of the first test pad exposed from the first insulating dielectric layer is shortened through heating and melting it by laser annealing. This ensures very good flatness of the surface to be bonded while enabling reduced process complexity, increased handling efficiency and lower cost.

In an embodiment of the present invention, there is provided a method of fabricating a semiconductor device, which includes:
in step S21, providing a substrate, the substrate is formed thereon with a first insulating dielectric layer and a first test pad in the first insulating dielectric layer, wherein a surface of the first test pad is at least partially exposed from the first insulating dielectric layer, and there is a probe mark with a protrusion resulting from testing with probe tips on the surface portion of the first test pad exposed from the first insulating dielectric layer;
in step S22, heating and melting the protrusion by laser annealing to reduce a height of the protrusion;
in step S23, forming a second insulating dielectric layer, which covers the first test pad and the first insulating dielectric layer; and
in step S24, planarizing the second insulating dielectric layer in such a manner that the remaining height of the protrusion is smaller than a height of a surface of the planarized second insulating dielectric layer.

The method according to the present embodiment will be described in greater detail below with reference to FIGS. 4a to 4d and FIGS. 5a to 5b. FIGS. 4a to 4d and FIGS. 5a to 5b are schematic longitudinal cross-sectional views of semiconductor devices.

In step S21, a substrate (not shown) is provided, the substrate is formed thereon with a first insulating dielectric layer 31 and a first test pad 32 in the first insulating dielectric layer 31. A surface of the first test pad 32 is at least partially exposed from the first insulating dielectric layer 31, and there is a probe mark with a protrusion resulting from testing with probe tips on the surface portion of the first test pad 32 exposed from the first insulating dielectric layer 31.

For more details concerning step S21, reference can be made to the above description in connection with step S11, and, therefore, further description thereof is omitted.

In step S22, a laser annealing process is performed to heat and melt the protrusion D3, thereby reducing the height of the protrusion D3.

For more details concerning step S22, reference can be made to the above description in connection with step S12, and, therefore, further description thereof is omitted.

Compared with the approach shown in FIGS. 1a and 1b in which the first test pad 15 is discarded and the external connection of the metal interconnect 14 is instead accomplished by the second test pad 16 and with the approach shown in FIGS. 2a and 2b in which a partial thickness of the test pad is removed and the test pad is then re-thickened, shortening the protrusion D3 or eliminating the protrusion D3 by fusing the protrusion D3 with the first test pad 32 through heating and melting the protrusion D3 with laser annealing according to the present embodiment entails a simplest process that solves the problem of protrusions in probe mark defects. Moreover, after the protrusion is shortened or eliminated, the first test pad 32 remains useful, resulting an additional significant reduction in process complexity.

In step S23, a second insulating dielectric layer 34 covering both the first test pad 32 and the first insulating dielectric layer 31 is formed. As shown in FIG. 4c, the second insulating dielectric layer 34 buries therein the third insulating material layer 313 and the portion of the first test pad 32 exposed from the third insulating material layer 313.

The second insulating dielectric layer 34 may be formed of at least one of silicon oxide, silicon nitride, silicon oxynitride, silicon carbonitride and other insulating materials.

In step S24, the second insulating dielectric layer 34 is planarized in such a manner that the remaining height of the protrusion D3 is smaller than a height of a surface of the planarized second insulating dielectric layer.

Since the remaining height of the protrusion D3 on the first test pad 32 is smaller than the height of the surface of the planarized second insulating dielectric layer 34, the second insulating dielectric layer 34 can cover both the first test pad 32 and the first insulating dielectric layer 31 even if it has a small thickness. This can make the subsequent processes (e.g., the subsequent formation of a conductive structure by etching and filling) easier, resulting in reductions in cost.

In order to ensure good flatness of the second insulating dielectric layer 34, the second insulating dielectric layer 34 may be planarized using a chemical mechanical polishing process.

Since the remaining height of the protrusion D3 on the first test pad 32 is smaller than the height of the surface of the planarized second insulating dielectric layer 34, the protrusion D3 will not be exposed during the planarization process on the second insulating dielectric layer 34, thus avoiding metal contamination in the planarization process.

The method may further include: providing a wafer (not shown) or die (not shown); and bonding the side of the second insulating dielectric layer 34 away from the substrate to the wafer or die. Because the surface of the second insulating dielectric layer 34 (on the side away from the substrate) has good flatness and is free of metal contamination, bonding can be normally accomplished between the surface of the second insulating dielectric layer 34 away from the substrate and the wafer or die, without any abnormality.

The structures shown in FIGS. 4a to 4d and FIGS. 5a to 5b may be formed on a wafer or die. That is the bonding of the side of the second insulating dielectric layer 34 away from the substrate to the wafer or die may be wafer-to-wafer bonding, wafer-to-die bonding, or die-to-die bonding.

The side of the second insulating dielectric layer 34 away from the substrate may be a front side of the wafer or die or a back side thereof opposite to the front side.

In case of only the first test pad 32 being formed in the first insulating dielectric layer 31, as shown in FIG. 4d, the method may further include, subsequent to the planarization of the second insulating dielectric layer 34 and prior to the bonding of the side of the second insulating dielectric layer 34 away from the substrate to the wafer or die, forming a conductive structure 35 in the second insulating dielectric layer 34, which is electrically connected at the bottom to the first test pad 32. Alternatively, the method may further include, subsequent to the bonding of the side of the second insulating dielectric layer 34 away from the substrate to the wafer or die, a conductive structure 35, which extends through the wafer or die into the second insulating dielectric layer 34 and is electrically connected to the first test pad 32.

In case of the first test pad 32 and the second test pad 36 being both formed in the first insulating dielectric layer 31 and both electrically connected at the bottom to the metal interconnect 33, the method may further include, subsequent to the planarization of the second insulating dielectric layer 34 and prior to the bonding of the side of the second insulating dielectric layer 34 away from the substrate to the wafer or die, forming a conductive structure 35 in the second insulating dielectric layer 34, which is electrically connected at the bottom to the first test pad 32, as shown in FIG. 5a, or a conductive structure 35, which extends through the second insulating dielectric layer 34 and a partial thickness of the third insulating material layer 313 in the first insulating dielectric layer 31 and is electrically connected to the second test pad 36, as shown in FIG. 5b. Alternatively, the method may further include, subsequent to the bonding of the side of the second insulating dielectric layer 34 away from the substrate to the wafer or die, a conductive structure 35, which extends through the wafer or die into the second insulating dielectric layer 34 and is electrically connected at the bottom to the first test pad 32, as shown in FIG. 5a, or a conductive structure 35, which extends through the wafer or die and the second insulating dielectric layer 34 into the first insulating dielectric layer 31 and is electrically connected at the bottom to the second test pad 36, as shown in FIG. 5b.

The conductive structure 35 may include a conductive plug (not labeled) and a bond pad (not labeled), which is exposed from the second insulating dielectric layer 34 and electrically connected at the bottom to the conductive plug. The conductive structure 35 is not limited to being structured in any of the ways shown in FIGS. 4d and 5a to 5b. Alternatively, the first test pad 32 or the second test pad 36 may be externally connected by at least two parallel conductive plugs, which provide reduced connection resistance and increased connection reliability.

As can be seen from the above description, in the method of fabricating a semiconductor device according to the present invention, heating and melting, by laser annealing, the protrusion in the probe mark resulting from testing with probe tips on the surface of the first test pad exposed from the first insulating dielectric layer so that the remaining height of the protrusion is smaller than the height of the surface of the planarized second insulating dielectric layer ensures good flatness of the surface to be bonded while enabling reduced process complexity and preventing metal contamination of the surface to be bonded.

The description presented above is merely that of a few preferred embodiments of the present invention and is not intended to limit the scope thereof in any sense. Any and all changes and modifications made by those of ordinary skill in the art based on the above teachings fall within the scope as defined in the appended claims.

What is claimed is:

1. A method of handling a test pad, comprising:
providing a substrate, wherein the substrate is formed thereon with a first insulating dielectric layer and a first test pad in the first insulating dielectric layer, a surface of the first test pad is at least partially exposed from the first insulating dielectric layer, and there is a probe mark with a protrusion resulting from testing with probe tips on the surface portion of the first test pad exposed from the first insulating dielectric layer; and
heating and melting the protrusion by laser annealing, thereby reducing a height of the protrusion.

2. The method of claim 1, wherein the protrusion projects from the surface of the first test pad beyond a surface of the first insulating dielectric layer.

3. The method of claim 1, wherein the laser annealing is accomplished with a laser beam, which is a monochromatic laser beam or a superimposition of at least two monochromatic laser beams.

4. The method of claim 1, wherein the protrusion is eliminated through heating and melting the protrusion by laser annealing and thereby fusing the protrusion with the first test pad.

5. The method of claim 1, wherein the laser annealing is accomplished with a laser beam with an energy density, which enables the first test pad to be heated at a temperature at least equal to a melting point of a material of the first test pad.

6. The method of claim 5, wherein the material of the first test pad is a metal alloy containing aluminum and copper, and wherein the heating temperature ranges from 600° C. to 700° C.

7. The method of claim 1, wherein the laser annealing is accomplished by continuous spot irradiation or point-by-point scanning irradiation, which does not affect any other region than the first test pad exposed from the first insulating dielectric layer.

8. The method of claim 1, wherein a temperature at a bottom side of the first test pad is not higher than 500° C.

9. The method of claim 1, further comprising, after the protrusion is heated and molten by laser annealing, cleaning the surface of the first test pad.

10. A method of fabricating a semiconductor device, comprising:
providing a substrate, wherein the substrate is formed thereon with a first insulating dielectric layer and a first test pad in the first insulating dielectric layer, a surface of the first test pad is at least partially exposed from the first insulating dielectric layer, and there is a probe mark with a protrusion resulting from testing with probe tips on the surface portion of the first test pad exposed from the first insulating dielectric layer;
heating and melting the protrusion by laser annealing, thereby reducing a height of the protrusion;
forming a second insulating dielectric layer, which covers the first test pad and the first insulating dielectric layer; and
planarizing the second insulating dielectric layer so that the remaining height of the protrusion is smaller than a height of a surface of the planarized second insulating dielectric layer.

11. The method of claim 10, wherein the protrusion is eliminated through heating and melting the protrusion by laser annealing and thereby fusing the protrusion with the first test pad.

12. The method of claim 10, wherein a metal interconnect is formed in the first insulating dielectric layer, wherein the bottom of the first test pad is electrically connected to the metal interconnect, and wherein the method further comprises:
providing a wafer or die; and bonding a side of the second insulating dielectric layer away from the substrate to the wafer or die.

13. The method of claim 12, further comprising, subsequent to the planarization of the second insulating dielectric layer and prior to the bonding of the side of the second insulating dielectric layer away from the substrate to the wafer or die,
forming a conductive structure electrically connected to the first test pad in the second insulating dielectric layer,
or subsequent to the bonding of the side of the second insulating dielectric layer away from the substrate to the wafer or die,
forming a conductive structure, which extends through the wafer or die into the second insulating dielectric layer and is electrically connected to the first test pad.

14. The method of claim 12, wherein a second test pad is further formed in the first insulating dielectric layer, the bottom of the second test pad electrically connected to the metal interconnect, and subsequent to the planarization of the second insulating dielectric layer and prior to the bonding of the side of the second insulating dielectric layer away from the substrate to the wafer or die, the method further comprising
forming a conductive structure, which extends through the second insulating dielectric layer into the first insulating dielectric layer and is electrically connected to the second test pad,
or subsequent to the bonding of the side of the second insulating dielectric layer away from the substrate to the wafer or die, the method further comprising
forming conductive structure, which extends through the wafer or die and the second insulating dielectric layer into the first insulating dielectric layer and is electrically connected to the second test pad.
